(19) United States
(12) Patent Application Publication
(10) Pub. No.: US 2006/0223222 A1
(43) Pub. Date: Oct. 5, 2006

(54) Organic thin film transistor array panel and method of manufacturing the same

(75) Inventors: Tae-Young Choi, Seoul (KR); Bo-Sung Kim, Seoul (KR)

Correspondence Address: David W. Heid;MacPHERSON KWOK CHEN & HELD LLP, Suite 226, 1762 Technology Drive, San Jose, CA, 95110, US

(73) Assignee: Samsung Electronics Co., Ltd.

(21) Appl. No.: 11/391,939

(22) Filed: Mar. 28, 2006

(30) Foreign Application Priority Data
Mar. 29, 2005 (KR) 10-2005-0025951

(51) Int. Cl. H01L 29/08; H01L 51/40; H01L 21/84; H01L 35/24; H01L 21/00; H01L 51/00

(52) U.S. Cl. 438/99; 438/149; 257/40

(57) ABSTRACT

An organic thin film transistor array panel comprises a substrate, a data line formed on the substrate, a gate line intersecting the data line on the substrate, said gate line comprising a gate electrode, a gate insulating layer formed on the gate line, said gate insulating layer including a contact hole, a source electrode formed on the gate insulating layer, said source electrode being coupled to the data line through the contact hole, a pixel electrode comprising a drain electrode, said drain electrode being provided opposite the source electrode with a gap, said gap being disposed on the gate electrode, a passivation layer including an opening through which the source electrode and the drain electrode are at least partially exposed, an organic semiconductor formed in the opening, and an overcoat layer formed on the organic semiconductor.

### CROSS-REFERENCE TO RELATED APPLICATION

This application claims priority to corresponding Korean Patent Application No. 10-2005-0025951 filed in the Korean Intellectual Property Office, Republic of Korea, on Mar. 29, 2005, the entire contents of which are incorporated by reference herein.

### BACKGROUND OF THE INVENTION

(a) Field of the Invention

The present invention relates to an organic thin film transistor (TFT) array panel and a method of manufacturing the same.

(b) Description of the Related Art

Organic TFTs have been studied as driving elements of next-generation display devices.

An organic TFT is obtained by replacing an inorganic material, such as Si, in a traditional, mainstream TFT with an organic material. Such a TFT can be easily fabricated at a low temperature using a vacuum deposition or spin coating process. In addition, since the organic TFT can be fabricated in the form of fiber or a film, it may be incorporated into a flexible display device.

The structure of an organic TFT array panel in which a plurality of organic TFTs are arranged in a matrix has many differences from that of typical TFT array panels with inorganic TFTs, and therefore a manufacturing method of such a panel differs from that of the typical panels.

It would therefore be desirable to develop a technique that is capable of improving the characteristics of an organic TFT by minimizing the influence of various process factors on the organic semiconductor of the TFT.

### SUMMARY OF THE INVENTION

In accordance with the present invention, a technique is provided which is capable of improving the characteristics of an organic TFT by minimizing the influence of various process factors on an organic semiconductor.

In accordance with the present invention, an organic thin film transistor array panel comprises a substrate, a data line formed on the substrate, a gate line intersecting the data line on the substrate, said gate line comprising a gate electrode, a gate insulating layer formed on the gate line, said gate insulating layer including a contact hole, a source electrode formed on the gate insulating layer, said source electrode being coupled to the data line through the contact hole, a pixel electrode comprising a drain electrode, said drain electrode being provided opposite the source electrode with a gap, said gap being disposed on the gate electrode, a passivation layer including an opening through which the source electrode and the drain electrode are at least partially exposed, an organic semiconductor formed in the opening, and an overcoat layer formed on the organic semiconductor.

A method of manufacturing the organic thin film transistor array panel comprises the steps of (A) forming a data line on a substrate, (B) forming an insulating layer on the data line, (C) forming a gate line on the insulating layer, (D) forming on the gate line a gate insulating layer having a contact hole through which the data line is at least partially exposed, (E) forming on the gate insulating layer a source electrode connected to the data line through the contact hole and a pixel electrode having a drain electrode facing the source electrode, (F) forming on the source electrode and the pixel electrode a passivation layer having an opening, (G) forming an organic semiconductor in the opening, and (H) forming an overcoat layer on the organic semiconductor

### BRIEF DESCRIPTION OF THE DRAWINGS

The present invention will become more apparent from the following detailed description of the embodiments thereof with reference to the accompanying drawings.

FIG. 1 is a layout view of an organic TFT array panel in accordance with an embodiment of the present invention.

FIG. 2 is a schematic cross-section taken along the line II-II of FIG. 1.

FIG. 3, FIG. 5, FIG. 7, FIG. 9, FIG. 11, and FIG. 14 are layout views illustrating subsequent process steps for the manufacturing of the organic TFT array panel shown in FIG. 1 and FIG. 2.

FIG. 4 is a sectional view of the TFT array panel shown in FIG. 3 taken along the line IV-IV.

FIG. 6 is a sectional view of the TFT array panel shown in FIG. 5 taken along the line VI-VI.

FIG. 8 is a sectional view of the TFT array panel shown in FIG. 7 taken along the line VIII-VIII.

FIG. 10 is a sectional view of the TFT array panel shown in FIG. 9 taken along the line X-X.

FIG. 12 is a sectional view of the TFT array panel shown in FIG. 11 taken along the line XII-XII.

FIG. 13 is a sectional view sequentially illustrating the intermediate steps of a method of manufacturing a TFT array panel of FIGS. 11 and 12.

FIG. 15 is a sectional view of the TFT array panel shown in FIG. 14 taken along the line XV-XV.

FIG. 16 and FIG. 17 are sectional view sequentially illustrating the intermediate steps of a method of manufacturing a TFT array panel of FIGS. 14 and 15.

FIGS. 18 to 20 are sectional views illustrating a method of manufacturing a TFT array panel according to another embodiment of the present invention.

### DETAILED DESCRIPTION

Embodiments of the present invention are described more fully hereinafter with reference to the accompanying drawings, in which embodiments of the invention are shown. The present invention may, however, be embodied in different forms and thus the present invention should not be construed as being limited to the embodiments set forth herein. Rather, these embodiments are provided so that this disclosure will be thorough and complete, and will fully convey the scope of the invention to those skilled in the art.

In the drawings, the thickness of the layers, films, and regions may be exaggerated for clarity. Like numerals refer to like elements throughout. When an element such as a layer, film, region, or substrate is referred to as being “on” another element, it can be provided directly on the other element or intervening elements may also be present.

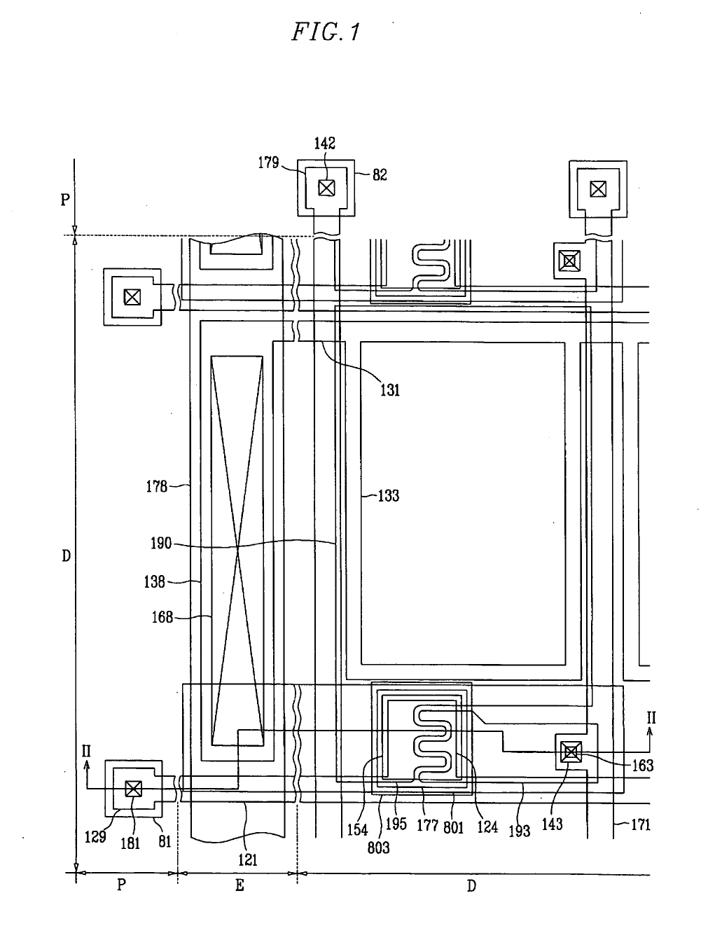

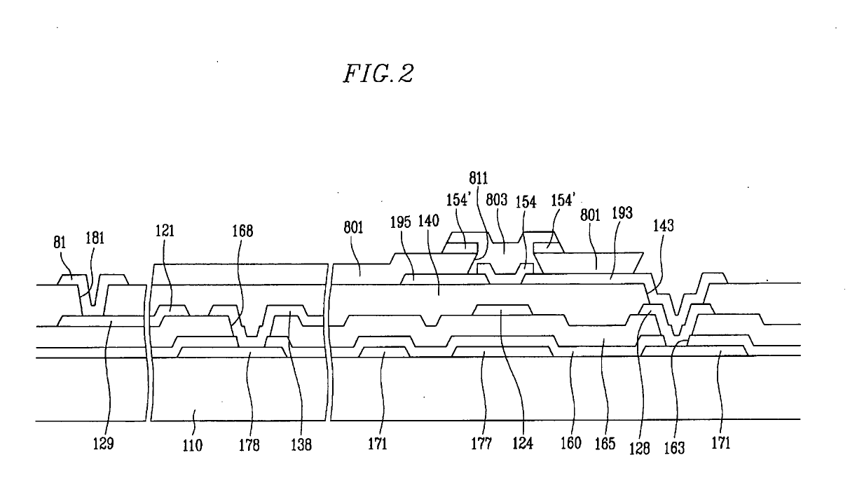

The structure of an organic TFT array panel according to a preferred embodiment of the present invention will be described with reference to FIG. 1 and FIG. 2.

FIG. 1 is a layout view of an organic TFT array panel according to a preferred embodiment of the present invention, and FIG. 2 is a schematic cross-sectional view taken along the line II-II of FIG. 1.

Referring to FIG. 1, the organic TFT array panel of this embodiment comprises a display region D in which a plurality of pixels are arranged and images are displayed, a pad region P in which pads for connecting external devices such as driving ICs are disposed, and an auxiliary region E in which auxiliary signal lines, such as a storage electrode connection part, an electrostatic discharging circuit, and the like, are disposed.

This organic TFT array panel is configured as follows.

Referring to FIG. 1 and FIG. 2, a plurality of data lines 171, a storage electrode line connection member 178, and a plurality of light-blocking members 177 are formed on a transparent insulating substrate 110 comprising, e.g., glass or plastic.

The data lines 171 for transmitting data voltages extend substantially in a vertical direction in the display region D. An end portion 179 of each data line 171 is provided in the pad region P and is provided with a larger width than other portions of the data line 171 in order to establish good contact with an external device or a different layer.

The storage electrode line connection member 178 for transmitting a common voltage is provided in the auxiliary region E, and extends in a vertical direction.

Each light-blocking member 177 is formed below an organic semiconductor 154 to prevent a photoleakage current from abruptly increasing in the organic semiconductor 154.

The data lines 171, the storage electrode line connection member 178, and the light-blocking members 177 may comprise a low resistivity metal such as gold (Au), silver (Ag), copper (Cu), aluminum (Al), or any alloys thereof, in order to reduce delay of the signals or voltage drop in the data lines 171, the storage electrode line connection member 178, and the light-blocking members 177. The data lines 171, the storage electrode line connection member 178, and the light-blocking members 177 may also be configured as a multi-layered structure including at least two conductive layers having different physical properties. In such a structure, one of the two layers comprises a low resistivity conductor, while the other layer comprises a conductor such as molybdenum (Mo), a Mo alloy (for example, MoW), or chrome (Cr), which have good physical, chemical, and electrical contact properties with other materials such as indium tin oxide (ITO) and indium zinc oxide (IZO).

The data lines 171, the storage electrode line connection member 178, and the light-blocking members 177 have thickness of about 1000 Å to about 3000 Å.

All lateral sides of the data lines 171, the storage electrode line connection member 178, and the light-blocking members 177 preferably form an angle of between about 30° and about 80° relative to the surface of the substrate 110.

A first interlayer insulating layer 160 is formed on the data lines 171, the storage electrode line connection member 178, and the light-blocking members 177. The first interlayer insulating layer 160 comprises an inorganic insulator such as silicon nitride SiNₓ or silicon oxide SiO₂.

A second interlayer insulating layer 165 is formed on the first interlayer insulating layer 160. The second interlayer insulating layer 165 comprises an organic insulator including at least one of polyacryl, polyimide, and benzocyclobutyne (C₁₀H₈), which have good durability. In other embodiments, either of the two interlayer insulating layers 160 and 165 may be omitted.

A plurality of contact holes 163 and 168 are formed in the first and second interlayer insulating layers 160 and 165, and the data lines 171 and the storage electrode line connection member 178 are partially exposed through the contact holes 163 and 168, respectively.

A plurality of gate lines 121, a plurality of contact members 128, and a plurality of storage electrode lines 131 are formed on the second interlayer insulating layer 165.

The gate lines 121 for transmitting gate signals are provided in the display region D, and extend substantially in a vertical direction to cross the data lines 171. Each gate line 121 includes a plurality of gate electrodes 124 protruding upward, as shown in FIG. 1. An end portion 129 of each gate line 121 is provided in the pad region P, and is formed with a larger width than other portions of the gate line 121 in order to provide good contact with an external device or a different layer.

The contact members 128 are connected to the data lines 171 through the contact holes 163 that are formed in the first and second interlayer insulating layers 160 and 165.

The storage electrode lines 131 are provided in the display region D, and extend substantially in a horizontal direction. Each storage electrode line 131 includes a plurality of storage electrodes 133. Each storage electrode 133 comprises two vertical lines that extend downward from the storage electrode line 131 between two adjacent data lines, and a horizontal line that connects both ends of the two vertical lines and is provided above the gate line 121. An end portion 138 of each storage electrode line 131 is provided in the auxiliary region E, and is formed with a greater width than other portions of the storage electrode line 131 to provide a good contact with an external device or a different layer. The end portions 138 are connected to the storage electrode line connection member 178 through the contact holes 168 that are formed in the first and second interlayer insulating layers 160 and 165.

The gate lines 121, the contact members 128, and the storage electrode lines 131 may comprise a low resistivity metal such as Au, Ag, Al, or any of alloys thereof, in order to reduce delay of the signals or voltage drop in the gate lines 121, the contact members 128, and the storage electrode lines 131. The gate lines 121, the contact members 128, and the storage electrode lines 131 may also be configured as a multi-layered structure including at least two conductive layers having different physical properties. In such a structure, one of the two layers comprises a low resistivity conductor, while the other layer comprises a conductor such as Mo, a Mo alloy (for example, MoW), or Cr, which have good physical, chemical, and electrical contact properties with other materials such as ITO and IZO.

The gate lines 121, the contact members 128, and the storage electrode lines 131 preferably for an angle of between about 30° and about 80° relative to the surface of the substrate 110.

A gate insulating layer 140 is formed on the substrate 110 with the gate lines 121, the contact members 128, and the storage electrode lines 131. The gate insulating layer 140 may comprise an inorganic insulator, such as SiNₓ or an organic insulator. Preferably, the gate insulating layer 140 comprises an organic or inorganic insulator, such as SiO₂, that is surface-treated with octadecyltrichlorosilane (OTS), parylene that is produced in a vacuum chamber by a chemical vapor deposition (CVD) process, or a hydrocarbon-based high molecular compound containing fluorine (F).

In embodiments in which the gate insulating layer 140 comprises parylene, the gate insulating layer 140 can exhibit good insulation properties because parylene has a very low dielectric constant. Parylene is very uniformly deposited over the entire area of the substrate 110. In this case, the thickness of a parylene layer can range from 1000 Å to several micrometers. In addition, parylene polymers are insoluble in all known organic solvents. Since the parylene deposition process may be performed at room temperature, the parylene layer undergoes no heat stress during the process. Moreover, etching of the parylene layer can be performed in an eco-friendly manner because it may be performed by a dry etching process using no solvent.

The gate insulating layer 140 may have a thickness of about 6000 Å to about 1.2 μm.

A plurality of contact holes 181 are formed in the gate insulating layer 140, and the end portions 129 of the gate lines 121 are exposed through the contact holes 181. A plurality of contact holes 142 are also formed in the gate insulating layer 140 and the first and second interlayer insulating layers 160 and 165. The end portions 179 of the data lines 171 are exposed through the contact holes 142. A plurality of contact holes 143 are also formed in the gate insulating layer 140. Each contact hole 143 is aligned with a contact hole 163 formed in the first and second interlayer insulating layers 160 and 165. The data lines 171, which are adjacent to the gate electrodes 124, are partially exposed through the contact holes 143 and 163.

In this case, the end portions 129 of the gate lines 121 and the end portions 179 of the data lines 171 are connected to external driving circuits through the contact holes 181 and 142 using a thin anisotropic conductive film. The external driving circuits may be mounted on the substrate 110 in the form of IC chips. Alternately, the external driving circuits (particularly, gate driving circuits) may be integrated into the substrate 110. In this case, the driving circuits are formed on the same layer as the organic TFTs, and the end portions 129 and 179 of the gate lines 121 and the data lines 171 are electrically coupled to output terminals of the driving circuits.

A plurality of source electrodes 193, a plurality of pixel electrodes 190, and a plurality of contact assistants 81 and 82 are formed on the gate insulating layer 140. The source electrodes 193 and the pixel electrodes 190 are provided in the display region D, while the contact assistants 81 and 82 are provided in the pad region P.

The source electrodes 193, the pixel electrodes 190, and the contact assistants 81 and 82 comprise a transparent conductor such as IZO or ITO, or a conductor having a high reflectance, and are formed to have thickness of about 300 Å to 800 Å. The pixel electrodes 190 are partially overlapped with the gate electrodes 124, and the overlapping portions form drain electrodes 195. The drain electrodes 195 receive data signals.

The source electrodes 193 are provided opposite the drain electrodes 195 with a gap, and are connected to the data lines 171 through the contact holes 143 and 163. A gap is disposed on the gate electrode 124. The outline of each source electrode 193 includes a wave-shaped portion, and the outline of the opposing drain electrode 195 is formed with a wave shape corresponding to the wave-shaped portion of the source electrode 193. The wave-shaped outlines are provided to maximize the length of the source and drain electrodes 193 and 195 within a given unit area.

Each pixel electrode 190 may partially overlap an adjacent gate line 121 and adjacent data line 171 to increase the aperture ratio. In other embodiments, such an overlap structure may be omitted.

The contact assistants 81 and 82 are connected to the end portions 129 of the gate lines 121 and the end portions 179 of the data lines 171 through the contact holes 181 and 142, respectively. The contact assistants 81 and 82 supplement adhesion between the exposed regions of the end portions 129 and 179 and exterior devices, and provide protection for the exposed regions of the end portions 129 and 179.

The contact members 128 are connected to the data lines 171 through the contact holes 163 that are formed in the first and second interlayer insulating layers 160 and 165. The contact members 128 are also connected to the source electrodes 193 through the contact holes 143 that are formed in the gate insulating layer 140. Since some organic layers, such as the second interlayer insulating layer 165 and the gate insulating layer 140, exist between the data lines 171 and the source electrodes 193, defective contact may occur if the data lines 171 are directly connected to the source electrodes 193. In this embodiment, the contact members 128 are provided between the data lines 171 and source electrodes 193 in order to prevent such a defective contact.

A passivation layer 801 is formed on the pixel electrodes 190 with the drain electrodes 195, and on the source electrodes 193. The passivation layer 801 comprises a photosensitive organic material, and has a thickness of about 8000 Å to about 2 μm.

The passivation layer 801 is provided with a plurality of openings 811, through which the source electrodes 193 and the drain electrodes 195 are partially exposed. In each opening 811, an island-shaped organic semiconductor 154 is formed. The organic semiconductor 154 is formed above the gate electrode 124, and is connected to the source electrode 193 and the drain electrode 195.

Each organic semiconductor 154 may comprise a high molecular material or a low molecular material, which is soluble in aqueous solutions and organic solvents. Generally, high molecular materials are deposited using a printing process because they are soluble in the organic solvents, while most of the low molecular materials are deposited using an evaporation process utilizing a shadow mask because they are typically insoluble in the organic solvents. However, low molecular materials which are soluble in organic solvents may be deposited using a printing process.

Each organic semiconductor 154 may comprise derivatives containing a substituent of tetracene or pentacene, oligothiophene in which 4, 5, 6, 7, or 8 thiophene rings are connected to each other at position 2 or 5 thereof, polythienylenevinylene, poly 3-hexylthiophene, phthalocyanine, or thiophene.

Each organic semiconductor 154 has a thickness of 300 Å to 1000 Å.

Since the organic semiconductors 154 are formed in the openings 811 of the passivation layer 801, they less affected by subsequent process steps.

Generally, the organic semiconductors 154 have low chemical resistance and low heat resistance. As a result, during subsequent process steps, high temperature, plasma, and chemical materials can easily deteriorate the organic semiconductors 154. For this reason, the organic semiconductors 154 are formed in the openings 811 of the passivation layer 801 such that the sides of the organic semiconductors 154 are sufficiently protected by the sidewalls of the openings 811 during subsequent process steps.

Each organic semiconductor 154 is covered with an overcoat layer 803. The overcoat layer 803 may comprise a positive or negative photosensitive organic insulator. The overcoat layer 803 fully covers the organic semiconductor 154, and fills the remaining space of the opening 811. Accordingly, the organic semiconductors 154 are protected by the overcoat layer 803 from external heat, plasma, and chemical materials.

The gate electrode 124, source electrode 193, drain electrode 195, and organic semiconductor 154 form a thin film transistor (TFT). A TFT channel is formed in the organic semiconductor 154 provided between the source electrode 193 and the drain electrode 195.

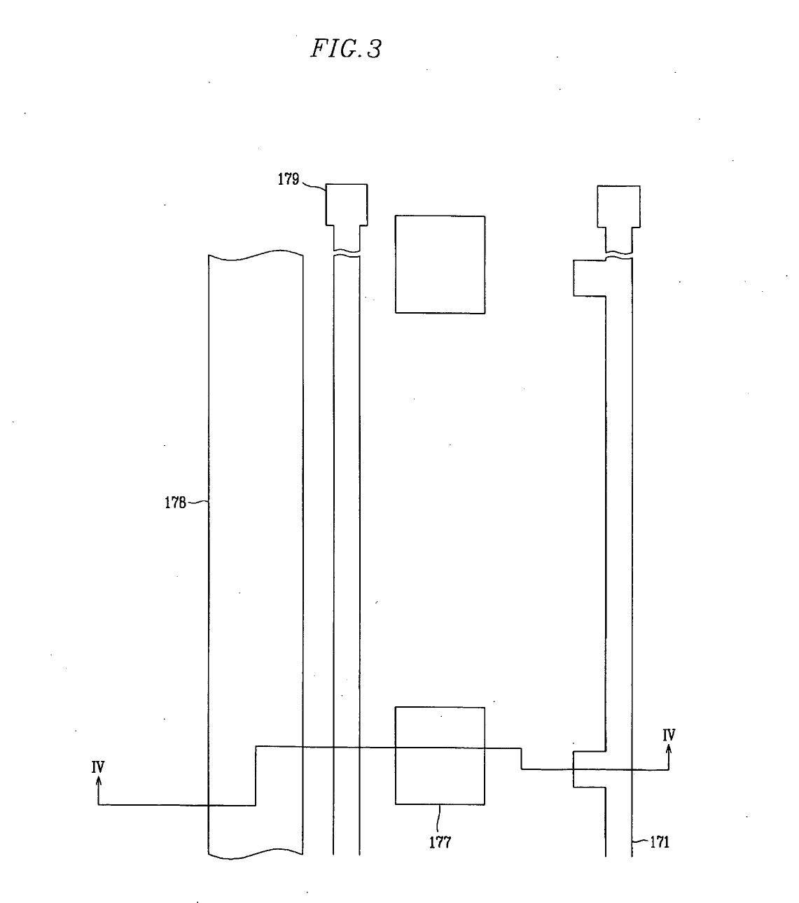

Hereinafter, a method of manufacturing the organic TFT array panel shown in FIG. 1 and FIG. 2 will be described in detail with reference to FIG. 3 through FIG. 20.

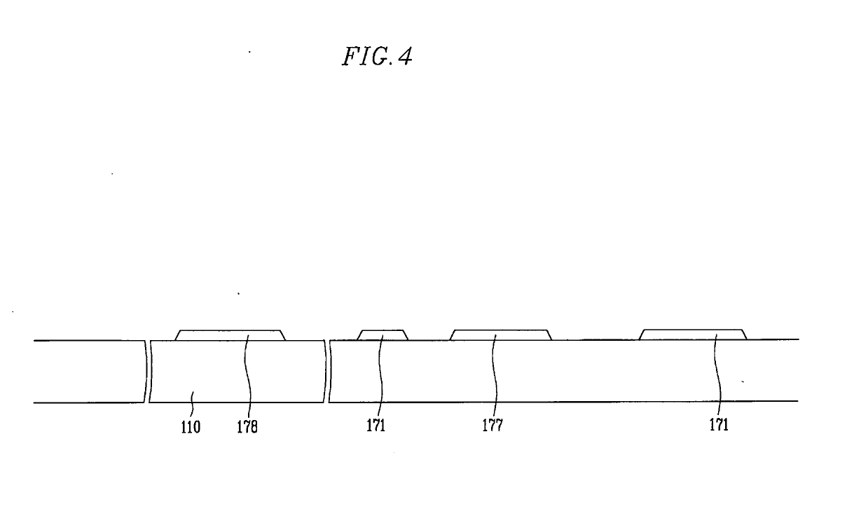

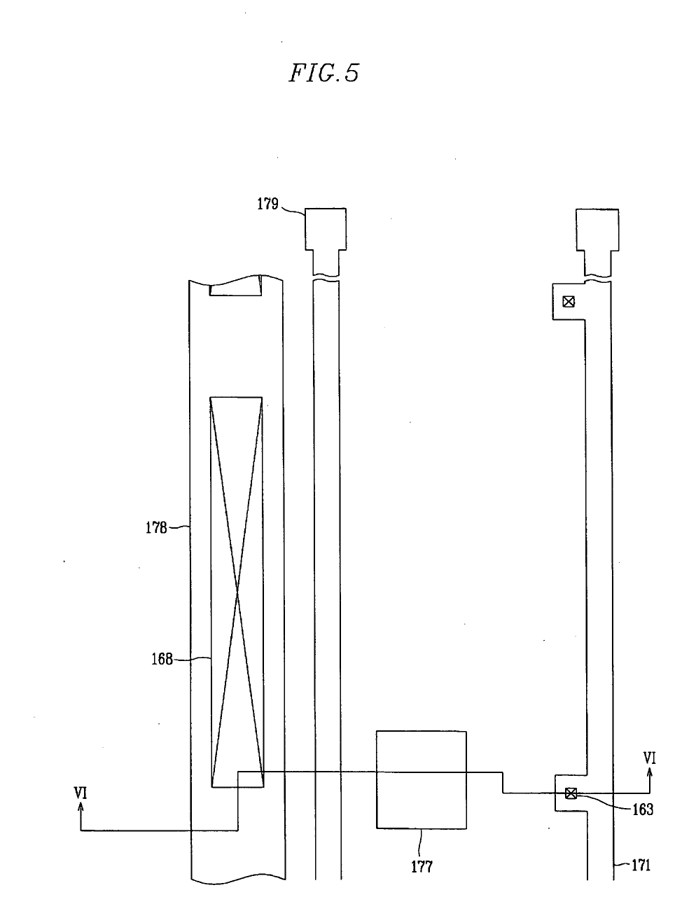

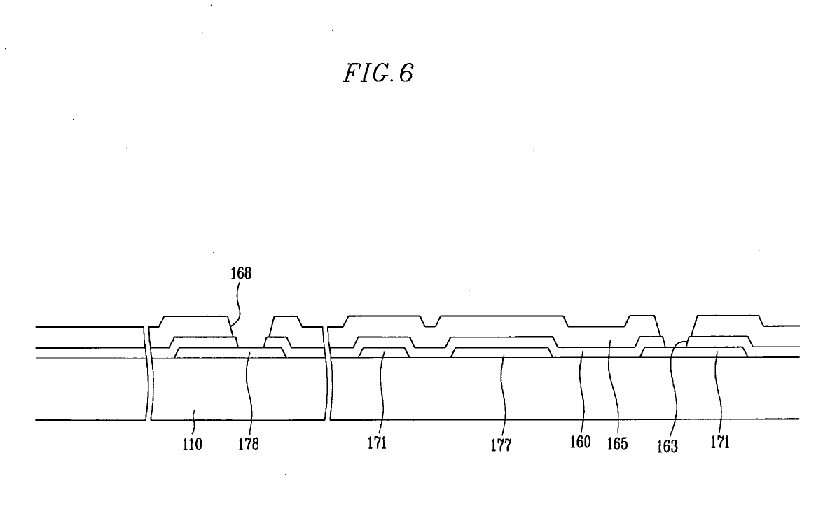

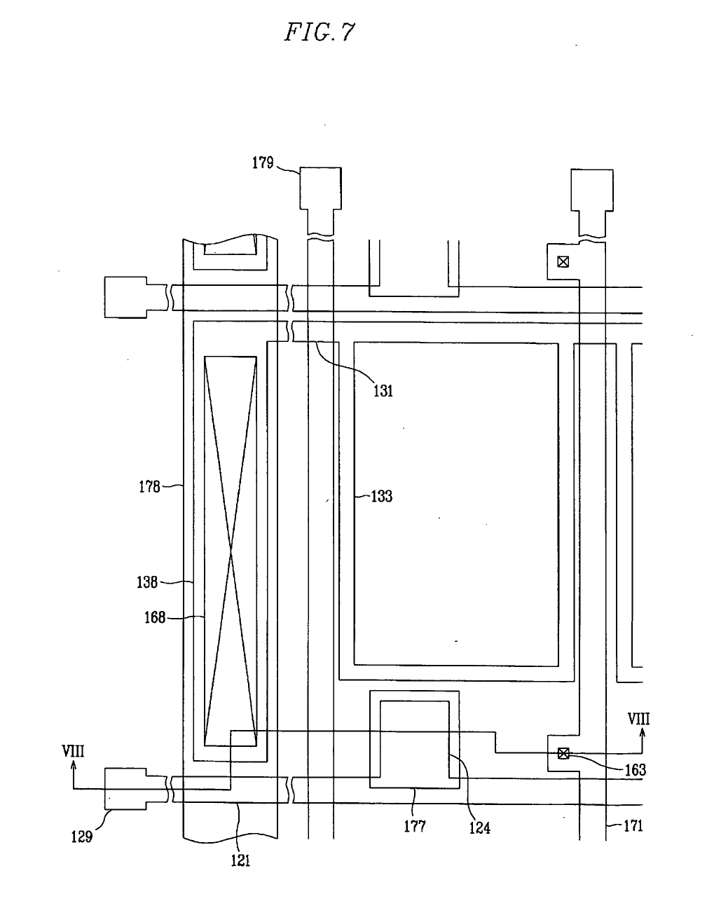

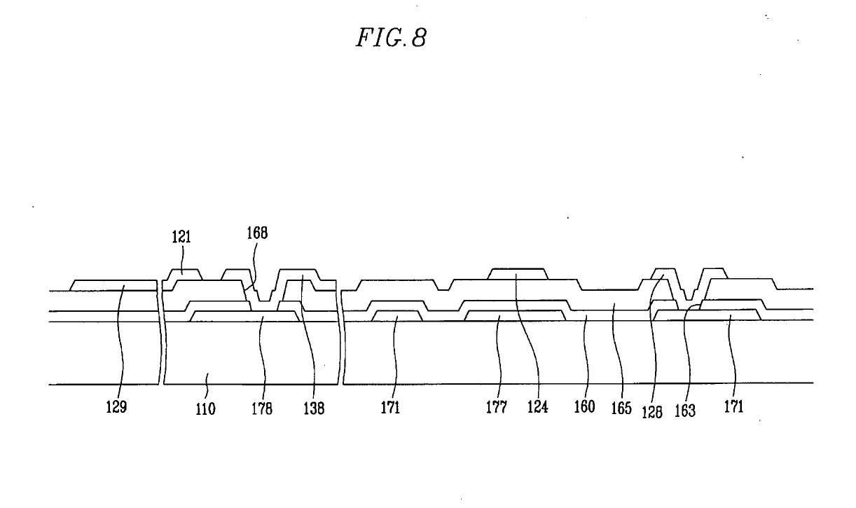

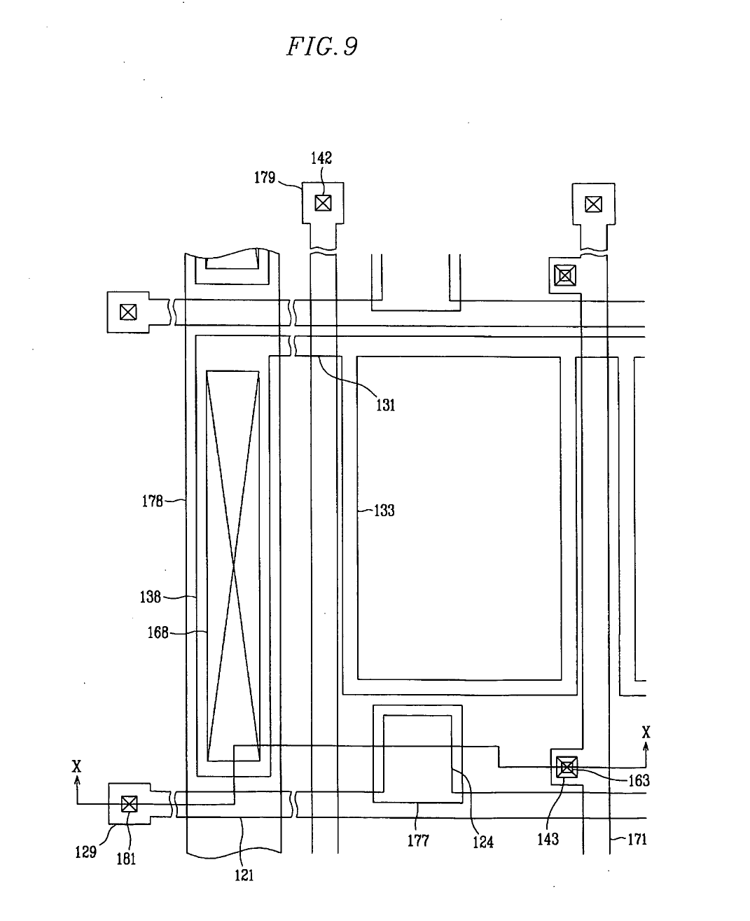

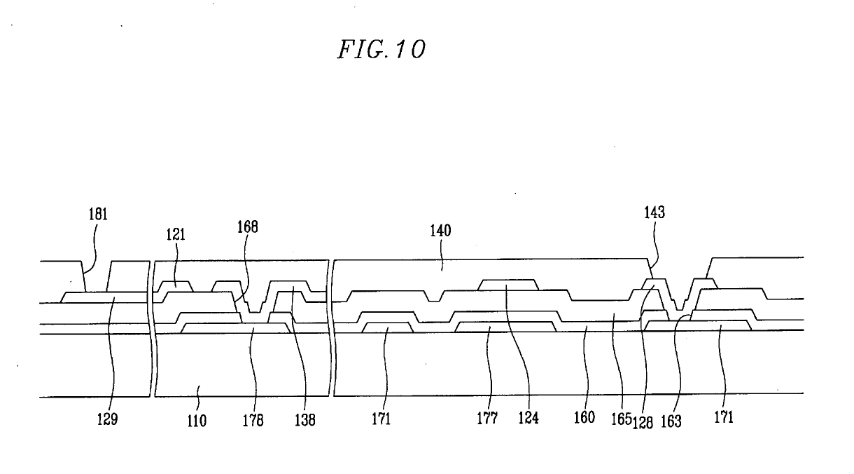

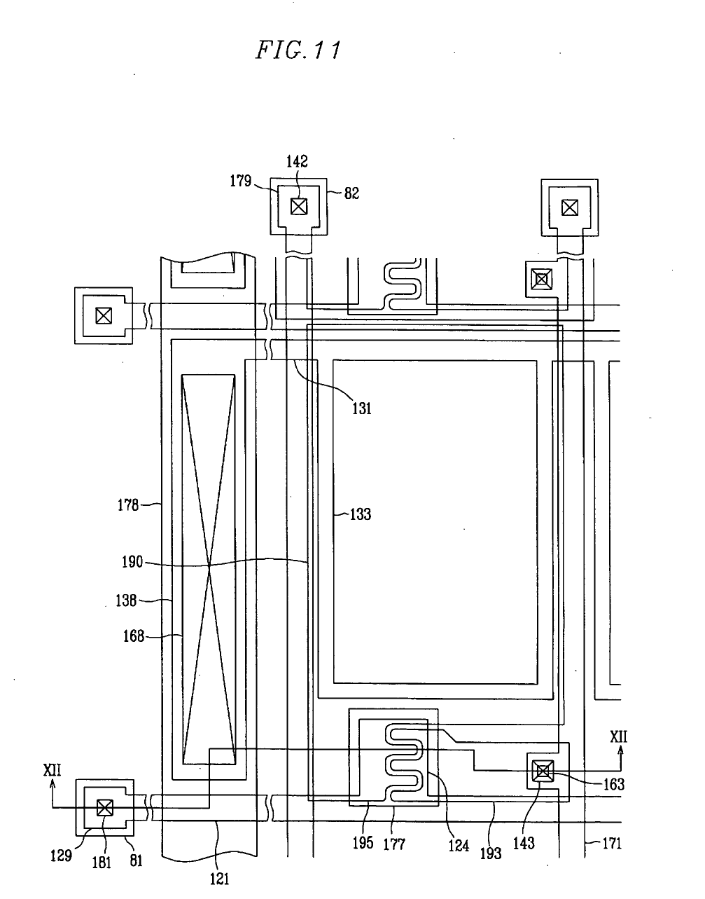

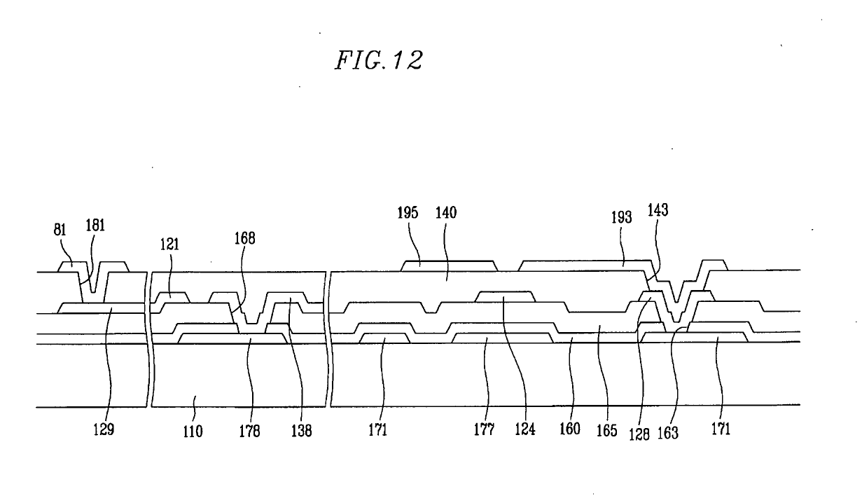

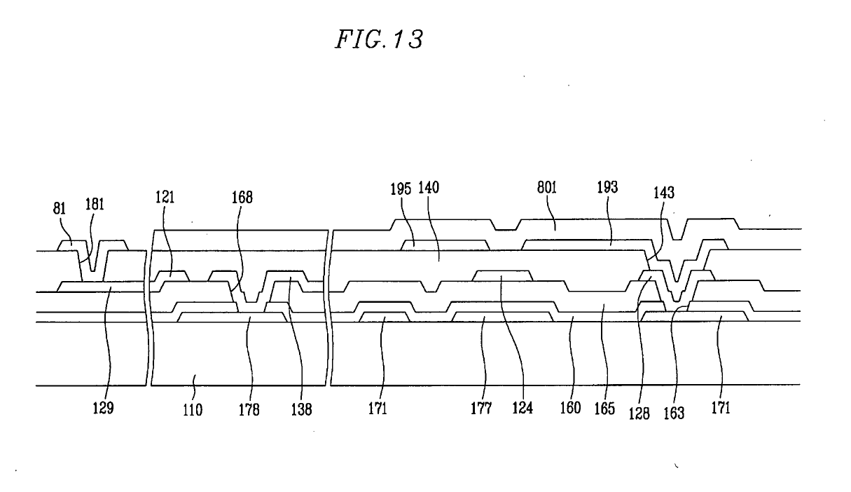

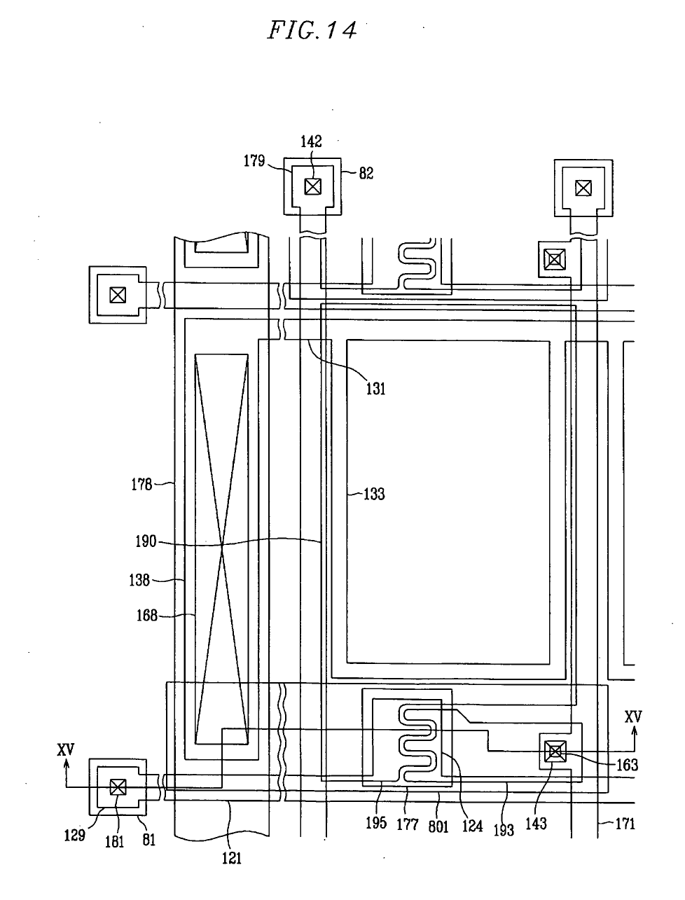

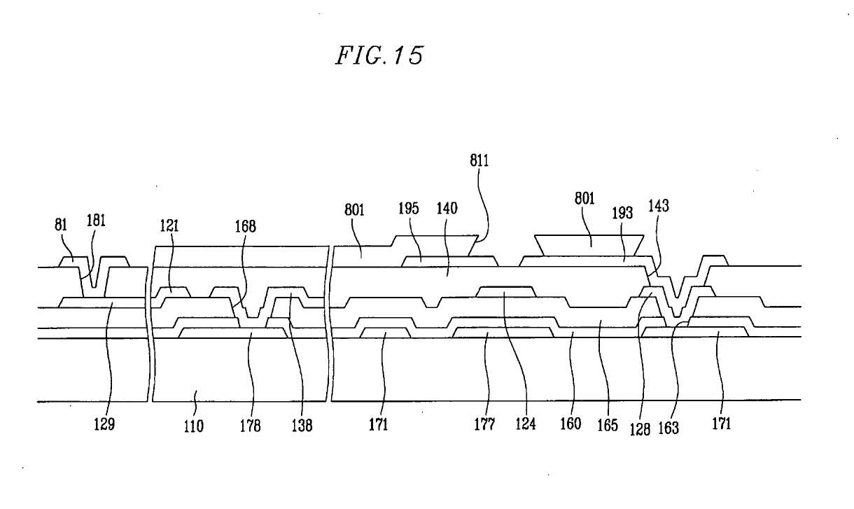

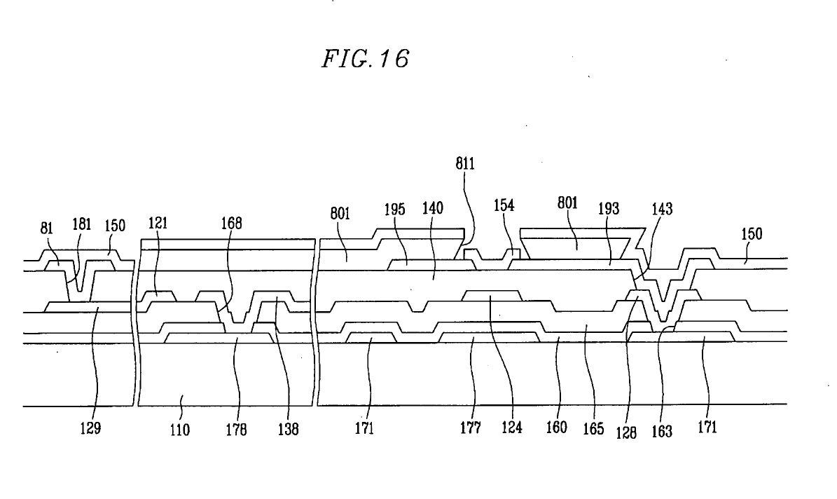

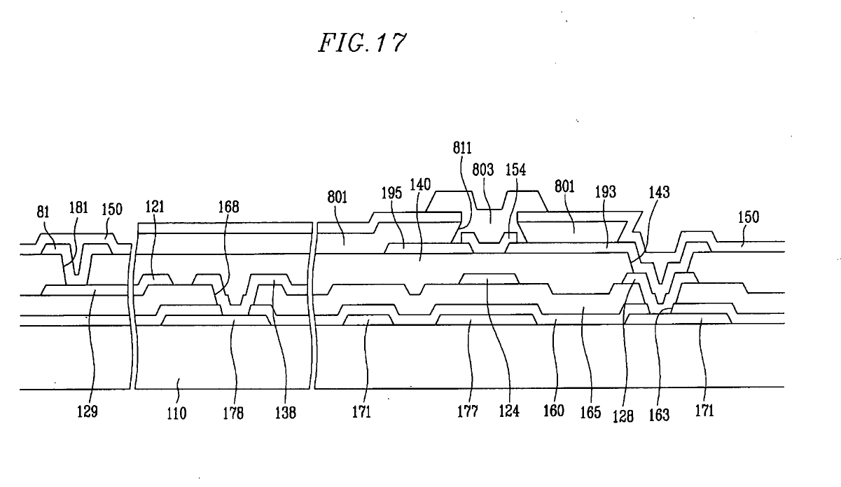

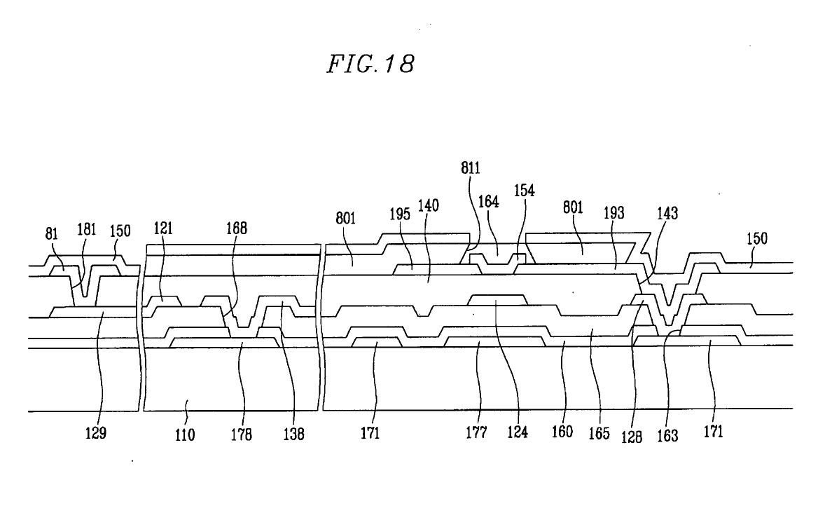

FIG. 3, FIG. 5, FIG. 7, FIG. 9, FIG. 11, and FIG. 14 are layout views illustrating subsequent process steps for the manufacturing of the organic TFT array panel shown in FIG. 1 and FIG. 2. FIG. 4 is a sectional view of the TFT array panel shown in FIG. 3 taken along the line IV-IV. FIG. 6 is a sectional view of the TFT array panel shown in FIG. 5 taken along the line VI-VI. FIG. 8 is a sectional view of the TFT array panel shown in FIG. 7 taken along the line VIII-VIII. FIG. 10 is a sectional view of the TFT array panel shown in FIG. 9 taken along the line X-X. FIG. 12 is a sectional view of the TFT array panel shown in FIG. 11 taken along the line XII-XII. FIG. 13 is a sectional view sequentially illustrating the intermediate steps of method of manufacturing a TFT array panel of FIGS. 11 and 12. FIG. 15 is a sectional view of the TFT array panel shown in FIG. 14 taken along the line XV-XV. FIG. 16 and FIG. 17 are sectional view sequentially illustrating the intermediate steps of a method of manufacturing a TFT array panel of FIGS. 14 and 15. FIGS. 18 to 20 are sectional views illustrating a method of manufacturing a TFT array panel according to another embodiment of the present invention.

The first step is described with reference to FIG. 3 and FIG. 4.

A metal layer is formed on an insulating substrate 110 comprising glass or plastic using a sputtering process. The metal layer may comprise a low resistivity metal such as Au, Ag, Cu, Al, or any alloys thereof, or may be configured as a multi-layered structure including at least a low resistivity conductive layer and a conductive layer having good contact properties with other materials.

The metal layer is then selectively etched by photolithography to form a plurality of data lines 171 with end portions 179, a storage electrode line connection member 178, and a plurality of light-blocking members 177, as shown in FIG. 3 and FIG. 4.

The next step is described with reference to FIG. 5 and FIG. 6.

An inorganic material such as SiNₓ is deposited on the entire substrate 110 such that a first interlayer insulating layer 160 is formed on the substrate 110, the data lines 171, the storage electrode line connection member 178, and the light-blocking members 177. Subsequently, a photosensitive organic material is deposited on the first interlayer layer 160 to form a second interlayer insulating layer 165. In this step, the first interlayer insulating layer 160 is formed using a CVD process at 250° C. to 400° C., while the second interlayer insulating layer 165 is formed using a spin coating process utilizing at least one of polyacryl, polyimide, and benzocyclobutyne (C₁₀H₈), which are in solution states. In other embodiments, either of the two interlayer insulating layers 160 and 165 may be omitted.

Next, the second interlayer insulating layer 165 is selectively exposed to light to produce a plurality of contact holes 163, 142, and 168, through which the data lines 171, the end portions 179 of the data lines 171, and the storage electrode line connection member 178 are individually exposed. Subsequently, a dry etching process for the first interlayer insulating layer 160 is performed using the second interlayer insulating layer 165 as a mask.

The next step is described with reference to FIG. 7 and FIG. 8.

A metal layer is formed on the second interlayer insulating layer 165. The metal layer may comprise Au, Ag, Cu, Al, or any alloys thereof, or may be configured as a multi-layered structure including at least a low resistivity conductive layer and a conductive layer having good contact properties with other materials.

The metal layer is then selectively etched using photolithography to form a plurality of gate lines 121 with gate electrodes 124, a plurality of contact members 128, and a plurality of storage electrode lines 131 with storage electrodes 133 and end portions 138. Here, the end portions 138 of the storage electrode lines 131 are connected to the storage electrode line connection member 178 through the contact holes 168.

The contact members 128 are connected to the data lines 171 through the contact holes 163 that are formed in the two interlayer insulating layers 160 and 165, in order to prevent defective contacts from generating between the underlying data lines 171 and overlying source electrodes 193.

The next step is described with reference to FIG. 9 and FIG. 10.

A gate insulating layer 140 is formed on the substrate 110 including the gate lines 121 with the gate electrodes 124, the contact members 128, and the storage electrode lines 131 with the storage electrodes 133 and the end portions 138.

The gate insulating layer 140 comprises an inorganic material or a photosensitive organic material. Preferably, the gate insulating layer 140 comprises a material selected from SiO₂ surface-treated with octadecyltrichlorosilane (OTS), parylene, and a hydrocarbon-based high molecular compound containing fluorine (F). The selected material may be deposited using a CVD process performed in a vacuum chamber. Alternately, the material may be spin-coated on the substrate 110 after dissolving the material in a solvent.

The gate insulating layer 140 is formed to have a thickness of about 6000 Å to about 1 μm.

Next, the gate insulating layer 140 is selectively exposed to light. As a result, a plurality of contact holes 143 and 181 are formed in the gate insulating layer 140, and the contact members 128 and the end portions 129 of the gate lines 121 are exposed through the contact holes 143 and 181, respectively.

The next step is described with reference to FIG. 11 and FIG. 12.

A conductor, such as amorphous ITO, may be deposited on the gate insulating layer 140 by sputtering performed at room temperature. The deposited amorphous ITO layer is then patterned using a weak-acid etchant containing an amine (NH₂) to form a plurality of source electrodes 193, a plurality of pixel electrodes 190 including a plurality of drain electrodes 195, and a plurality of contact assistants 81 and 82, as shown in FIGS. 11 and 12. As mentioned above, the amorphous ITO layer can be etched by a weak-acid etchant, in contrast with the other conductive layers or crystalline ITO layers that can be etched only by strong-acid etchants. If a strong-acid etchant is used in this step, the etchant may create cracks in the gate insulating layer 140 by attacking the gate insulating layer 140. Even worse, such an etchant may erode different conductive layers underlying the gate insulating layer 140 by soaking through cracks formed in the gate insulating layer 140.

Next, the amorphous ITO may be crystallized.

In other embodiments, the source electrodes 193, the pixel electrodes 190 including the drain electrodes 195, and the contact assistants 81 and 82 may comprise a transparent conductor such as IZO or ITO, or a reflective conductor such as Au or Al, instead of ITO.

The next step is described with reference to FIG. 13.

A passivation layer 801 is formed on the entire substrate 110 including the pixel electrodes 190 and the source electrodes 193. The passivation layer 801 comprises a negative-type photosensitive organic material, and is formed to have a thickness of about 8000 Å to about 2 μm.

The next step is described with reference to FIG. 14 and FIG. 15.

The passivation layer 801 is then selectively exposed to light through a predetermined pattern mask. As a result, a plurality of openings 811 are formed in the passivation layer 801, and the source electrodes 193 and the drain electrodes 195 are partially exposed through the openings 811.

The next step is described with reference to FIG. 16.

An organic semiconductor layer 150 is formed on the entire passivation layer 801 using a deposition process or a spin coating process.

Partial portions of the organic semiconductor layer 150, which are provided in the openings 811, form island-shaped organic semiconductors 154.

The next step is described with reference to FIG. 17.

A photosensitive organic material is coated on the entire substrate 110 having the organic semiconductor layer 150 and the organic semiconductors 154. The remaining spaces of the openings 811 are also filled with the photosensitive organic material. The organic layer is then selectively exposed to light though a mask, thereby forming an overcoat layer 803 that fully covers the organic semiconductors 154.

Since the organic semiconductors 154 have low chemical resistance and low heat resistance, high temperatures, plasma, and chemical materials applied during subsequent process steps may deteriorate the organic semiconductors 154. For this reason, the organic semiconductors 154 are formed in the openings 811 of the passivation layer 801 such that the sides of the organic semiconductors 154 are sufficiently protected by the sidewalls of the openings 811 during subsequent process steps.

Next, the semiconductor layer 150 is etched using the overcoat layer 803 as a mask. As a result, the organic TFT array panel is completed as shown in FIG. 1 and FIG. 2.

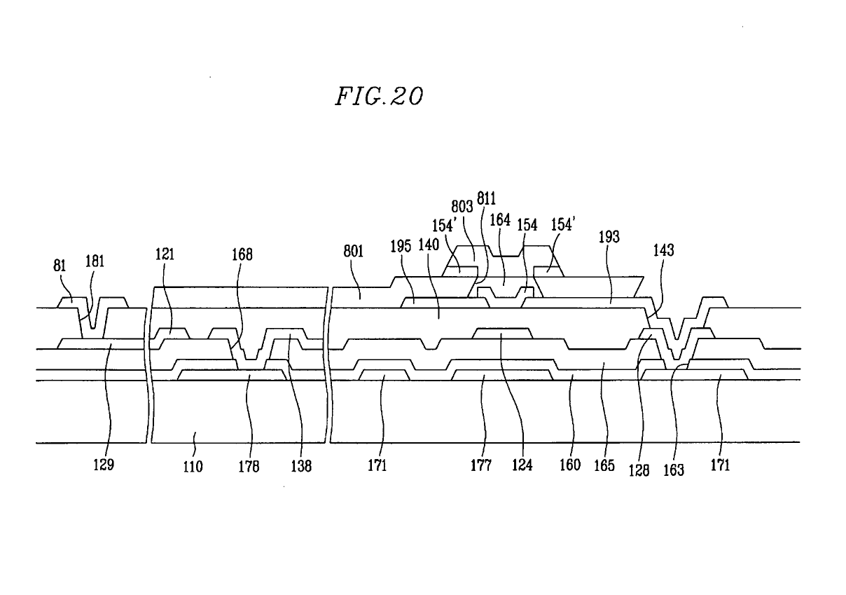

Hereinafter, the structure of an organic TFT array panel according to another embodiment of the present invention will be described with reference to FIG. 1 and FIG. 20.

A plurality of data lines 171, a storage electrode line connection member 178, and a plurality of light-blocking members 177 are formed on a transparent insulating substrate 110.

A first interlayer insulating layer 160 is formed on the data lines 171, the storage electrode line connection member 178, and the light-blocking members 177.

A second interlayer insulating layer 165 is formed on the first interlayer insulating layer 160. In other embodiments, either of the two interlayer insulating layers 160 and 165 may be omitted.

A plurality of contact holes 163 and 168 are formed in the first and second interlayer insulating layers 160 and 165, and data lines 171 and the storage electrode line connection member 178 are partially exposed through the contact holes 163 and 165, respectively.

A plurality of gate lines 121 for transmitting gate signals, a plurality of contact members 128, and a plurality of storage electrode lines 131 are formed on the second interlayer insulating layer 165. Each contact member 128 is formed on a partial portion of the data line 171.

A gate insulating layer 140 is formed on the entire substrate 110 including the gate lines 121, the contact members 128, and the storage electrode lines 131. The gate insulating layer 140 may comprise an organic insulator or an organic insulator. Preferably, the gate insulating layer 140 comprises an organic or inorganic insulator, such as SiO₂ that is surface-treated with octadecyltrichlorosilane (OTS), parylene that is produced in a vacuum chamber by chemical vapor deposition (CVD) process, or a hydrocarbon-based high molecular compound containing fluorine (F).

The gate insulating layer 140 may have a thickness of about 6000 Å to about 1.2 μm.

A plurality of contact holes 181 are formed in the gate insulating layer 140, and the end portions 129 of the gate lines 121 are exposed through the contact holes 181. A plurality of contact holes 142 are also formed in the gate insulating layer 140 and the first and second interlayer insulating layers 160 and 165. The end portions 179 of the data lines 171 are exposed through the contact holes 142. A plurality of contact holes 143 are also formed in the gate insulating layer 140. Each contact hole 143 is aligned with a contact hole 163 formed in the first and second interlayer insulating layers 160 and 165. The data lines 171, which are adjacent to the gate electrodes 124, are partially exposed through the contact holes 143 and the contact holes 163.

A plurality of source electrodes 193, a plurality of pixel electrodes 190, and a plurality of contact assistants 81 and 82 are formed on the gate insulating layer 140. The source electrodes 193 and the pixel electrodes 190 are provided in the display region D, while the contact assistants 81 and 82 are provided in the pad region P.

The source electrodes 193, the pixel electrodes 190, and the contact assistants 81 and 82 comprise a transparent conductor such as IZO or ITO, or a conductor having a high reflectance.

The pixel electrodes 190 are partially overlapped with the gate electrodes 124, and the overlapping portions form drain electrodes 195. The drain electrodes 195 receive data signals.

The source electrodes 193 are provided opposite the drain electrodes 195 with a gap, and are connected to the data lines 171 through the contact holes 143 and 163. The gap is disposed on the gate electrode 124.

The outline of each source electrode 193 includes a wave-shaped portion, and the outline of the opposing drain electrode 195 is formed with a wave shape corresponding to the wave-shaped portion of the source electrode 193. The wave-shaped outlines are provided to maximize the length of the source and drain electrodes 193 and 195 within a given unit area.

Each pixel electrode 190 may partially overlap an adjacent gate line 121 and adjacent data line 171 to increase the aperture ratio. In other embodiments, such an overlap structure may be omitted.

A passivation layer 801 is formed on the pixel electrodes 190 and the source electrodes 193. The passivation layer 801 comprises a negative type of organic material with photosensitivity, and has a thickness of about 8000 Å to about 2 μm.

The passivation layer 801 is provided with a plurality of openings 811, through which the source electrodes 193 and the drain electrodes 195 are partially exposed. In each opening 811, an organic semiconductor 154 is formed. The organic semiconductor 154 overlaps the gate electrode 124, and is connected to the source electrode 193 and the drain electrode 195.

Each opening 811 formed in the passivation layer 801 is filled with an insulating pattern 164, thereby enclosing the organic semiconductor 154 within the insulating pattern 164. This insulating pattern 164 comprises an insulator that is applicable to a dry etching process and a low temperature deposition process, such as polyvinyl alcohol or a high molecular compound containing fluorine (F), which has no effect on the organic semiconductors 154.

An overcoat layer 803 is formed on the insulating patterns 164.

Hereinafter, a method of manufacturing the organic TFT array panel shown in FIG. 1 and FIG. 20 will be described in detail with reference to FIG. 3 through FIG. 16 and FIG. 18 through FIG. 20.

The first step is described with reference to FIG. 3 and FIG. 4.

A metal layer is formed on an insulating substrate 110 made of glass or plastic using a sputtering process. The metal layer is then selectively etched using photolithography, such that a plurality of data lines 171 with end portions 179, a storage electrode line connection member 178, and a plurality of light-blocking members 177 are formed, as shown in FIG. 3 and FIG. 4.

The next step is described with reference to FIG. 5 and FIG. 6.

An inorganic material such as SiNₓ is deposited on the entire substrate 110 such that a first interlayer insulating layer 160 is formed on the substrate 110, the data lines 171, the storage electrode line connection member 178, and the light-blocking members 177. Subsequently, a photosensitive organic material is deposited on the first interlayer layer 160 to form a second interlayer insulating layer 165. In other embodiments, either of the two interlayer insulating layers 160 and 165 may be omitted.

Next, the second interlayer insulating layer 165 is selectively exposed to light to produce a plurality of contact holes 163, 142, and 168, through which the data lines 171, the end portions 179 of the data lines 171, and the storage electrode line connection part 178 are individually exposed, are produced. Subsequently, a dry etching process for the first interlayer insulating layer 160 is performed using the second interlayer insulating layer 165 as a mask.

The next step is described with reference to FIG. 7 and FIG. 8.

A metal layer is formed on the second interlayer insulating layer 165. The metal layer is then selectively etched by photolithography to form a plurality of gate lines 121 with gate electrodes 124, a plurality of contact members 128, and a plurality of storage electrode lines 131 with storage electrodes 133 and end portions 138. Here, the end portions 138 of the storage electrode lines 131 are connected to the storage electrode line connection part 178 through the contact holes 168.

The next step is described with reference to FIG. 9 and FIG. 10.

A gate insulating layer 140 is formed on the entire substrate 110 including the gate lines 121 with the gate electrodes 124, the contact members 128, and the storage electrode lines 131 with the storage electrodes 133 and the end portions 138.

Next, the gate insulating layer 140 is selectively exposed to light. As a result, a plurality of contact holes 143 and 181 are formed in the gate insulating layer 140, and the contact members 128 and the end portions 129 of the gate lines 121 are exposed through the contact holes 143 and 181, respectively.

The next step is described with reference to FIG. 11 and FIG. 12.

A conductor, such as amorphous ITO, may be deposited on the gate insulating layer 140. The deposited conductive layer is then patterned to form a plurality of source electrodes 193, a plurality of pixel electrodes 190 including drain electrodes 195, and a plurality of contact assistants 81 and 82, as shown in FIG. 12.

A partial portion of each pixel electrode 190 forms a drain electrode 195. Each drain electrode 195 is provided opposite a source electrode 193. The outline of each source electrode 193 includes a wave-shaped portion, and the outline of the opposing drain electrode 195 is formed with a wave shape corresponding to the wave-shaped portion of the source electrode 193. The wave-shaped outlines are provided to maximize the length of the source and drain electrodes 193 and 195 within a given unit area.

The source electrodes 193 are connected to the data lines 171 through the contact holes 143 and 163 to receive data signals therefrom.

The next step is described with reference to FIG. 13.

A passivation layer 801 is formed on the entire substrate 110 including the pixel electrodes 190 and the source electrodes 193. The passivation layer 801 comprises a negative-type photosensitive organic material, and is formed to a thickness of about 8000 Å to about 2 μm.

The next step is described with reference to FIG. 14 and FIG. 15.

The passivation layer 801 is then selectively exposed to light through a predetermined pattern mask. As a result, a plurality of openings 811 are formed in the passivation layer 801, and the source electrodes 193 and the drain electrodes 195 are partially exposed through the openings 811.

The next step is described with reference to FIG. 16.

An organic semiconductor layer 150 is formed on the entire passivation layer 801 using a deposition process or spin coating process.

Partial portions of the organic semiconductor layer 150, which are provided in the openings 811, form island-shaped organic semiconductors 154.

The next step is described with reference to FIG. 18.

Each opening 811 formed in the passivation layer 801 is filled with an insulating pattern 164. At this time, the organic semiconductor 154 is enclosed with the insulating pattern 164. This insulating pattern 164 comprises an insulator that is applicable to a dry etching process and a low temperature deposition process, such as polyvinyl alcohol or a high molecular compound containing fluorine (F), which has no thermal and chemical effect on the organic semiconductors 154.

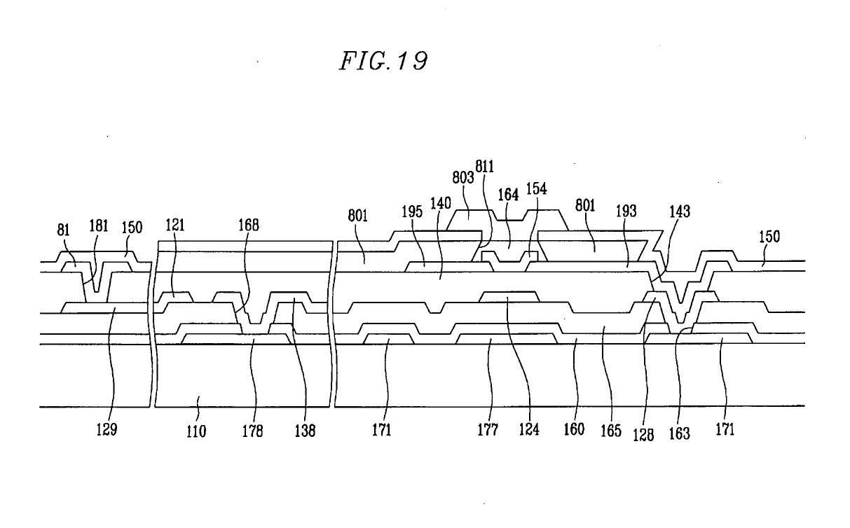

Next, a photosensitive organic material is coated on the entire substrate 110 having the organic semiconductor layer 150 and the organic semiconductors 154. The remaining spaces of the openings 811 are also filled with the photosensitive organic material. The organic layer is then selectively exposed to light though a mask, thereby forming a overcoat layer 803 that fully covers the organic insulating patterns 164, as shown in FIG. 19.

Then, the semiconductor layer 150 is etched using the overcoat layer 803 as a mask. As a result, the organic TFT array panel is completed as shown in FIG. 1 and FIG. 20.

In accordance with the above-described embodiments of the present invention, the organic semiconductors are less influenced by various process factors during manufacturing, because the organic semiconductors are formed in the openings of the passivation layer and are covered with the overcoat layer. Accordingly, the characteristics of the organic TFTs having these organic semiconductors are improved.

The present invention should not be considered limited to the particular examples described above, but rather should be understood to cover all aspects of the invention recited in the attached claims. Various modifications, equivalent processes, as well as numerous structures to which the present invention may be applicable will be readily apparent to those of skill in the art to which the present invention is directed upon review of the instant specification.

What is claimed is:

1. An organic thin film transistor (TFT) array panel comprising:
a substrate;
a data line formed on the substrate;
a gate line intersecting the data line on the substrate, said gate line comprising a gate electrode;
a gate insulating layer formed on the gate line, said gate insulating layer including a contact hole;
a source electrode formed on the gate insulating layer, said source electrode being coupled to the data line through the contact hole;
a pixel electrode comprising a drain electrode, said drain electrode being provided opposite the source electrode with a gap, said gap being disposed on the gate electrode;
a passivation layer including an opening through which the source electrode and the drain electrode are at least partially exposed;
an organic semiconductor formed in the opening; and
an overcoat layer formed on the organic semiconductor.

2. The organic TFT array panel of claim 1, wherein:
the passivation layer comprises a photosensitive organic material; and
the overcoat layer comprises a photosensitive organic material.

3. The organic TFT array panel of claim 1, wherein the passivation layer comprises a negative-type photosensitive organic material.

4. The organic TFT array panel of claim 1, further comprising a semiconductor pattern interposed between the passivation layer and the overcoat layer.

5. The organic TFT array panel of claim 4, wherein the semiconductor pattern and the organic semiconductor comprise the same material.

6. The organic TFT array panel of claim 1, wherein the organic semiconductor is fully enclosed with the passivation layer and the overcoat layer.

7. The organic TFT array panel of claim 1, further comprising an insulation pattern formed on the organic semiconductor.

8. The organic TFT array panel of claim 1, wherein the insulation pattern comprises a fluoride-based hydrocarbon compound or polyvinyl alcohol.

9. The organic TFT array panel of claim 1, further comprising an insulating layer formed between the data line and the gate line.

10. The organic TFT array panel of claim 9, wherein the insulating layer comprises a first insulating layer comprising silicon nitride (SiNₓ) and a second insulating layer comprising an organic insulator.

11. The organic TFT array panel of claim 1, further comprising a light-blocking member formed beneath the organic semiconductor, said light-blocking member comprising a conductive material.

12. The organic TFT array panel of claim 1, further comprising:
a storage electrode line connection member formed on the same layer as the data line; and
a storage electrode line connected to the storage electrode line connection member, said storage electrode line being formed on the same layer as the gate line.

13. A method of manufacturing an organic thin film transistor array panel, comprising the steps of:
(A) forming a data line on a substrate;
(B) forming an insulating layer on the data line;
(C) forming a gate line on the insulating layer;
(D) forming on the gate line a gate insulating layer having a contact hole through which the data line is at least partially exposed;
(E) forming on the gate insulating layer a source electrode connected to the data line through the contact hole, and a pixel electrode having a drain electrode facing the source electrode;
(F) forming on the source electrode and the pixel electrode a passivation layer having an opening;
(G) forming an organic semiconductor in the opening; and
(H) forming an overcoat layer on the organic semiconductor.

14. The method of claim 13, wherein:
the passivation layer comprises a photosensitive organic material; and
the overcoat layer comprises a photosensitive organic material.

15. The method of claim 13, wherein said forming the organic semiconductor in the opening comprises forming an organic semiconductor layer on the entire passivation layer.

16. The method of claim 15, wherein:
said forming the overcoat layer on the organic semiconductor comprises forming the overcoat layer on the organic semiconductor layer; and
after forming the overcoat layer on the organic semiconductor layer, etching the organic semiconductor layer the overcoat layer as a mask.

17. The method of claim 13, wherein said forming the organic semiconductor in the opening is performed by one of a spin coating process, a deposition process, and a printing process.

18. The method of claim 13, wherein after said forming the organic semiconductor in the opening, the opening is filled with an insulating material.

19. The method of claim 18, wherein the insulating material is a fluoride-based hydrocarbon compound or polyvinyl alcohol.

20. The method of claim 13, wherein said forming the source electrode and the pixel electrode comprises:
(E1) depositing an ITO layer at room temperature; and
(E2) selectively etching the ITO layer.

21. The method of claim 20, wherein said selectively etching the ITO layer is performed using an etchant with a basic compound.

22. The method of claim 13, wherein said forming the insulating layer on the data line comprises:
(B1) forming a first insulating layer comprising silicon nitride (SiNₓ) on the data line; and
(B2) forming a second insulating layer comprising an organic material on the first insulating layer.
